(19) United States
(12) Patent Application Publication
(10) Pub. No.: US 2008/0117084 A1
(43) Pub. Date: May 22, 2008

(54) Soft pack keyboard and manufacturing method thereof

(75) Inventor: Wei-Hsien Huang, Taipei (TW)

Correspondence Address: BIRCH STEWART KOLASCH & BIRCH, PO BOX 747, FALLS CHURCH, VA, 22040-0747, US

(73) Assignee: INVENTEC CORPORATION

(21) Appl. No.: 11/600,127

(22) Filed: Nov. 16, 2006

(51) Int. Cl. H03K 17/94

(52) U.S. Cl. 341/22

(57) ABSTRACT

A soft pack keyboard and a manufacturing method thereof are provided. The method comprises first putting a soft packing film cover on a keyboard common base, and then inserting a key thin layer between the keyboard common base and the soft packing film cover, wherein the keyboard common base has a plurality of keys, the key thin layer has characters or numbers printed at positions corresponding to the keys, and the soft packing film cover makes the key thin layer fixed on the keyboard common base.

### BACKGROUND OF TH INVENTION

1. Field of Invention

The present invention relates to a keyboard, and more particularly to a soft pack keyboard and a manufacturing method thereof.

2. Related Art

Keyboards are devices for inputting information in electronic products. So-called information can be classified into two types, namely character information and control information.

For character information, characters are input to electronic products using keys on a keyboard printed with various alphanumeric characters and symbols. As for control information, keys on the keyboard such as F1, Esc, and Delete are used to control electronic products to satisfy the demands of the users in particular circumstances.

In the age of science and technology, with the fast development of information, users, when selecting products, are not limited to any particular fixed style. From among products of various styles and features, and with various functions designed for different groups of users, users can choose more suitable products. Taking the main fitting of peripheral consumptive material, the keyboard, as an example, products include various styles and features, such as ergonomic keyboards, wireless keyboards, and multimedia keyboards, and the different types of keyboards all have their supporters.

Among PC keyboards of different countries or manufactures, the characters on the keys or the key layouts may be different from one another. Currently, standard keyboards mainly have 104 keys or 107 keys. The keyboard having 104 keys is also referred to as a Win 95 keyboard, and the keyboard having 107 keys is also referred to as a Win 98 keyboard that, compared with the keyboard having 104 keys, further comprises power management keys including Sleep mode, Wake Up, and Power keys. For users not used to the keyboard having 107 keys, the additional three keys replace original keys, which may cause inconvenience for some people. Among standard keyboards, the layouts of the function keys, such as “\”, “BackSpace”, “Enter”, and “Windows”, are different, wherein some “Enter” keys are big in size while some are small, and some “\” keys are located above the “Enter” key while some are located below the “Enter” key.

Therefore, because users come from different nationalities and have different habits, and the like, characters printed on PC keyboards must be diverse. In order to meet the requirements of a specific marketing area, characters on the keyboard must be specifically customized corresponding to the marketing area due to cultural differences among individual marketing areas and different characters of individual nations. However, if the lead time of production or material stock is too long, overall delivery will be affected.

Further, electronic products such as mobile phones, PDAs, and telephones also adopt keyboard input devices. Due to different customs, characters, and marks of each country, characters on keyboards must be specifically customized in order to meet the requirements of specific marketing areas. Otherwise, excessively long lead time of production or material stock will affect overall delivery.

### SUMMARY OF THE INVENTION

In view of the above problems, a main object of the present invention is to provide a soft pack keyboard and a manufacturing method thereof, for solving the problem existing in the prior art, that is, an long lead time affects the overall delivery of keyboards.

A soft pack keyboard and a manufacturing method thereof are provided. The method comprises putting a soft pack film cover on a keyboard common base; then inserting a key thin layer between the keyboard common base and the soft packing film cover, wherein the keyboard common base has a plurality of keys, the key thin layer are printed with characters or numbers at positions corresponding to the keys; and the soft packing film cover fixes the key thin layer on the keyboard common base.

According to the present invention, the key thin layers with the already printed characters or numbers are directly fixed on the keyboard common base, so the time for printing on each key of the keyboard characters or numbers according to different nations can be greatly reduced.

It is an advantage of the present invention that the present manufacturing method puts the soft packing film cover on the keyboard common base, then inserting the key thin layer with characters or numbers printed in advance between the keyboard common base and the soft packing film cover, thus, the delivery time of keyboards can be significantly reduced.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only for, and which thus is not limitative of the present invention, and wherein:

FIG. 1 is a schematic view of a soft pack keyboard and the manufacturing method thereof according to a preferred embodiment of the present invention.

### DETAILED DESCRIPTION OF THE INVENTION

Specific embodiments accompanied with the drawings are described herein below to illustrate the content of the present invention in detail. The symbols in the illustration refer to the symbols in the drawings.

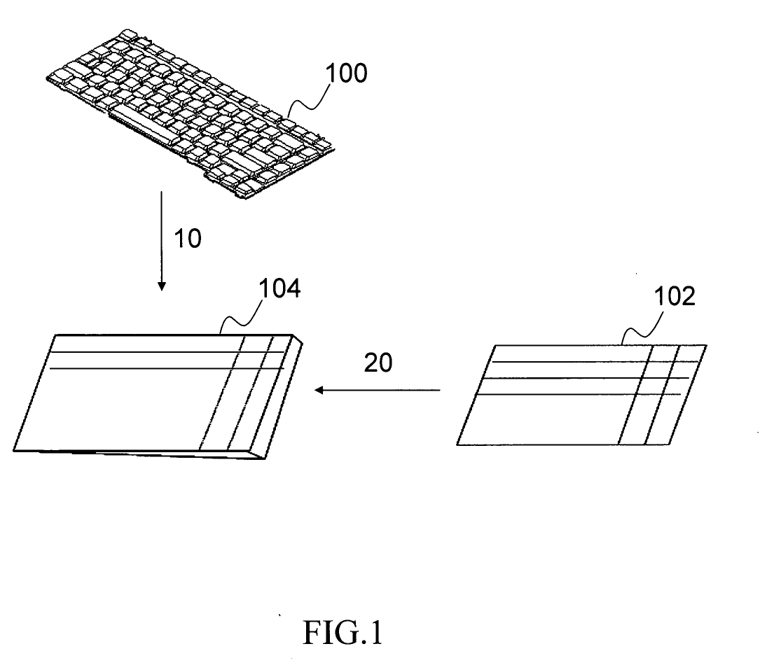

FIG. 1 is a schematic view of a soft pack keyboard and the manufacturing method thereof according to a preferred embodiment of the present invention. As shown in FIG. 1, a soft pack keyboard disclosed in the present invention comprises a keyboard common base 100, a key thin layer 102, and a soft packing film cover 104. The keyboard common base 100 has a plurality of keys. The key thin layer 102 has characters or numbers printed at the positions corresponding to the keys. The soft packing film cover 104 fixes the key thin layer on the keyboard common base.

As shown in FIG. 1, a method of manufacturing a soft pack keyboard disclosed in the present invention is first to put the soft packing film cover 104 on the keyboard common base 100 having a plurality of keys (step 10). Then, insert the key thin layer 102 with characters or numbers printed at positions corresponding to the keys between the keyboard common base 100 and the soft packing film cover 104 (step 20), for fixing the key thin layer 102 on the keyboard common base 100 with the soft packing film cover 104. The method for fixing the key thin layer 102 on the keyboard common base 100 further comprises coating a layer of adhesive such as a hot melt adhesive on the key thin layer 102; then inserting the key thin layer 102 in the soft packing film cover 104 and heating it, such that the key thin layer 102 is strongly fixed on the keyboard common base 100 by using the adhesive.

The key layout of the above keyboard common base includes, for example, the conventional 101 keys, 102 keys, or common 104 keys, 107 keys, or 110 keys used for windows software. The key layout can further includes an arrangement of hot keys, track balls, digitizing tablets, and the like, and the overall applications thereof include different electronic products such as mobile phones, PDAs, and telephones.

The characters or numbers on the above key thin layer can be printed in advance according to different nations or customer demands. And the material of the key thin layer is, for example, paper, plastic, or another material that is adapted to be used in printing and can be formed as thin layers.

The material of the above soft packing film cover comprises PE, PET, PVC, PP, PS, or a combination thereof. The material of the soft packing film cover can be added with additives as required. The additives are, for example, plasticizer, anti-shock modifier, chemical foaming agent, cross linking agent, coupling agent, nucleating agent, flame retardant, thermal stabilizer, antioxidant, light stabilizer, antistatic agent, conserving agent, release agent, lubricant, anti-caking agent, processing aids, or combinations thereof.

A soft pack keyboard disclosed in the present invention is suitable for being printed with the specifically customized characters or numbers thereon in advance according to the requirements depending on cultural differences among different marketing areas and different characters among nations. Therefore, the lead time of production or material stocking is greatly reduced, and thereby the whole delivery rate is enhanced.

According to the method of manufacturing a soft pack keyboard of the present invention, the key thin layer with the characters or numbers printed in advance is directly fixed on the blank keyboard. With this method, the rapid assembly can be achieved, and it is unnecessary to print characters or numbers on each key of the keyboard as in conventional technology, thus greatly reducing the manufacturing time of the keyboard.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A soft pack keyboard, comprising:
a keyboard common base having a plurality of keys;
a key thin layer having characters or numbers printed at positions corresponding to the keys; and
a soft packing film cover for fixing the key thin layer on the keyboard common base.

2. The soft pack keyboard as claimed in claim 1, wherein the key layout on the keyboard common base comprises 101 keys, 102 keys, 104 keys, 107 keys, or 110 keys, and hot keys, track balls, or digitizing tablets.

3. The soft pack keyboard as claimed in claim 1, wherein the keyboard is applicable to push-key style electronic products including computers, mobile phones, PDAs, telephones, or combinations thereof.

4. The soft pack keyboard as claimed in claim 1, wherein the characters or numbers on the key thin layer are printed according to different nations.

5. The soft pack keyboard as claimed in claim 1, wherein the material of the key thin layer comprises paper or plastic.

6. The soft pack keyboard as claimed in claim 1, wherein the material of the soft packing film cover comprises PE, PET, PVC, PP, PS, or combinations thereof.

7. The soft pack keyboard as claimed in claim 1, wherein the material of the soft packing film further comprises an additive.

8. The soft pack keyboard as claimed in claim 6, wherein the additive comprises plasticizer, anti-shock modifier, chemical foaming agent, cross linking agent, coupling agent, nucleating agent, flame retardant, thermal stabilizer, antioxidant, light stabilizer, antistatic agent, conserving agent, release agent, lubricant, anti-caking agent, processing aids, or a combination thereof.

9. A method of manufacturing the soft pack keyboard, comprising:
covering a soft packing film cover on a keyboard common base having a plurality of keys; and
inserting a key thin layer having characters or numbers printed at positions corresponding to the keys between the keyboard common base and the soft packing film cover, such that the key thin layer is fixed on the keyboard common base by the soft packing film cover.

10. The method of manufacturing the soft pack keyboard as claimed in claim 9, wherein the process for fixing the key thin layer on the keyboard common base further comprises using an adhesive.
